(19) United States
(12) Patent Application Publication
(10) Pub. No.: US 2014/0202525 A1
(43) Pub. Date: Jul. 24, 2014

(54) SOLAR MODULE MOUNTING BRACKET AND ASSEMBLIES

(71) Applicant: SunEdison, LLC, Beltsville, MD (US)

(72) Inventors: Steven Howard Janssens, San Francisco, CA (US); Paul Joseph Silberschatz, San Francisco, CA (US); Jesus Beltran, Sunnyvale, CA (US); Daniel Freymann Koelker, Palo Alto, CA (US)

(73) Assignee: SunEdison, LLC, Beltsville, MD (US)

(21) Appl. No.: 14/241,706

(22) PCT Filed: Aug. 30, 2012
(86) PCT No.: PCT/US12/53151

§ 371 Date: Feb. 27, 2014

Related U.S. Application Data
(60) Provisional application No. 61/530,106, filed on Sep. 1, 2011.

(51) Int. Cl. H01L 31/042; F16B 2/20; F16M 13/02; F24J 2/52

(52) U.S. Cl. CPC H01L 31/0422; F24J 2/5211; F16B 2/20; F16M 13/02
USPC 136/251; 126/704; 248/226.11; 248/222.14; 24/542; 248/575

(57) ABSTRACT

A mounting bracket for use with a solar module is disclosed. The mounting bracket includes a foot including a first wall and a second wall oriented substantially orthogonal to the first wall, the first wall including serrations configured to engage serrations on a rail to adjust a height of the rail with respect to the foot. The mounting bracket further includes a backing configured to be coupled to the foot and secure the mounting bracket to the rail.

### CROSS-REFERENCE TO RELATED APPLICATIONS

This application claims priority to U.S. Provisional Application No. 61/530,106 filed Sep. 1, 2011, the entire disclosure of which is hereby incorporated by reference in its entirety.

### FIELD

This disclosure generally relates to mounting systems for solar modules and, more specifically, to brackets for mounting solar modules to a mounting surface.

### BACKGROUND

Solar modules are devices which convert solar energy into other forms of useful energy (e.g., electricity or thermal energy). Such modules are typically positioned above an underlying support surface by a rack. This rack may be configured to position the solar module at an angle relative to the support surface to minimize an angle of incidence between the solar module and the sun's rays. Minimizing this angle of incidence increases the amount of solar energy gathered by the solar module.

Racks are typically formed from a plurality of structural members. These members may be assembled into a rack at a factory or other remote site and then transported to an installation location in this assembled state. In other methods, the structural members are transported to an installation location and then assembled to form the racks on site.

Regardless of whether a rack is assembled at a remote location or at a site of installation, in general, the solar modules are mounted to the racks, and the racks are mounted to the support surface at the installation site. During or after installation, it may be desirable to adjust a position of the solar modules and/or racks with respect to the support surface.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a mounting bracket for use with a solar module. The mounting bracket includes a foot including a first wall and a second wall oriented substantially orthogonal to the first wall, the first wall including serrations configured to engage serrations on a rail to adjust a height of the rail with respect to the foot. The mounting bracket further includes a backing configured to be coupled to the foot and secure the mounting bracket to the rail.

Another aspect of the present disclosure is a mounting assembly for use with a solar module. The mounting assembly includes a rail including a top, a first wall, and a second wall that define a slot, the first wall including an interior surface having serrations. The mounting assembly further includes at least one mounting bracket coupled to the rail. The mounting bracket includes a foot positioned in the slot, the foot comprising serrations that engage the rail serrations, wherein the foot serrations and the rail serrations facilitate adjusting a height of the rail with respect to the foot. The mounting bracket further includes a backing coupled to the foot to secure the mounting bracket to the rail.

Yet another aspect of the present disclosure is a mounting assembly for use with a solar module. The mounting assembly includes a rail including a top, a first wall, and a second wall that define a slot, the first wall including an interior surface. The mounting assembly includes at least one mounting bracket coupled to the rail. The mounting bracket includes a foot positioned in the slot and releasably engaging the interior surface to facilitate adjusting a height of the rail with respect to the foot, and a backing coupled to the foot to secure the mounting bracket to the rail.

Another aspect of the present disclosure is a component mounting bracket for use with a solar module mounting rail. The component mounting bracket includes a clip and a support shelf. The clip includes a first jaw and a second jaw. The first jaw includes serrations configured to engage serrations on a wall of a rail to couple the component mounting bracket to the rail. The second jaw is configured to contact a surface of the wall of the rail opposite the rail serrations. The support shelf is configured to support and couple a component to the component mounting bracket.

Still another aspect of the present disclosure is a wire clip assembly for use with a solar module mounting rail. The component mounting bracket includes a finger and a clip. The finger includes serrations configured to engage serrations on a wall of a rail. The clip defines a receptacle configured to engage an external ledge of the rail. The finger and the clip are configured to cooperatively couple the wire clip to the rail. The finger and the clip cooperatively define at least a portion of a wire channel between the wire clip and the rail when the wire clip is coupled to the rail.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of an example solar module;

FIG. 2 is a cross-sectional view of the solar module shown in FIG. 1 taken along the line A-A;

FIG. 3 is a front, perspective view of an example mounting bracket for use with the solar module shown in FIG. 1;

FIG. 4 is a front, exploded view of the mounting bracket shown in FIG. 3;

FIG. 5 is a back, perspective view of the mounting bracket shown in FIG. 3;

FIG. 6 is a side view of an example mounting assembly;

FIG. 7 is an enlarged view of a portion of FIG. 6;

FIG. 8 is a perspective view the mounting assembly shown in FIG. 6;

FIG. 9 is a side view of an example inverter bracket assembly;

FIG. 10 is a bottom, perspective view of the inverter bracket assembly shown in FIG. 9;

FIG. 11 is a side view of an example wire clip assembly; and

FIG. 12 is a bottom, perspective view of the wire clip assembly shown in FIG. 9.

Like reference symbols in the various drawings indicate like elements.

### DETAILED DESCRIPTION

The embodiments described herein generally relate to solar modules. More specifically, embodiments described herein relate to brackets for mounting solar modules to a surface.

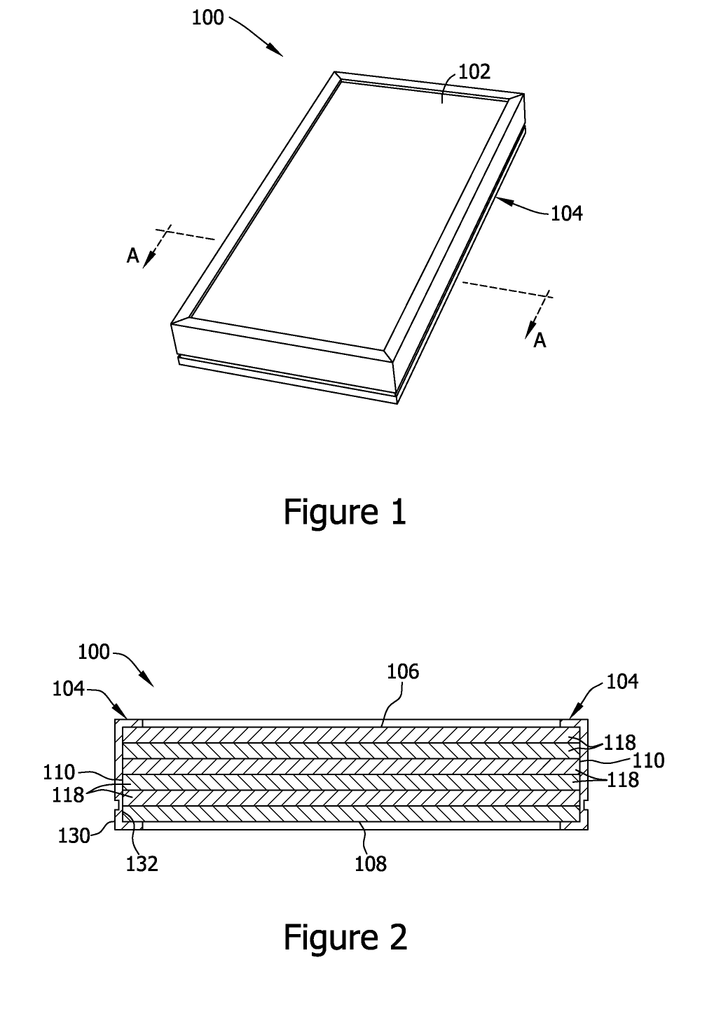

Referring initially to FIGS. 1 and 2, a solar module of one embodiment is indicated generally at 100. A perspective view of solar module 100 is shown in FIG. 1. FIG. 2 is a cross sectional view of solar module 100 taken at line A-A shown in FIG. 1. Solar module 100 includes a solar panel 102 and a frame 104 circumscribing solar panel 102.

Solar panel 102 includes a top surface 106 and a bottom surface 108 (shown in FIG. 2). Edges 110 extend between top surface 106 and bottom surface 108. In this embodiment, solar panel 102 is rectangular shaped. In other embodiments, solar panel 102 may have any suitable shape.

As shown in FIG. 2, the solar panel 102 has a laminate structure that includes several layers 118. Layers 118 may include for example glass layers, non-reflective layers, electrical connection layers, n-type silicon layers, p-type silicon layers, and/or backing layers. In other embodiments, solar panel 102 may have more or fewer, including one, layers 118, may have different layers 118, and/or may have different types of layers 118.

As shown in FIG. 1, frame 104 circumscribes solar panel 102. Frame 104 is coupled to solar panel 102, as best shown in FIG. 2. Frame 104 assists in protecting edges 110 of solar panel 102. Exemplary frame 104 includes an outer surface 130 spaced apart from solar panel 102 and an inner surface 132 adjacent solar panel 102. Outer surface 130 is spaced apart from and substantially parallel to inner surface 132. In the exemplary embodiment, frame 104 is made of aluminum. More particularly, in some embodiments frame 104 is made of 6000 series anodized aluminum. In other embodiments, frame 104 may be made of any other suitable material providing sufficient rigidity including, for example, rolled or stamped stainless steel, plastic or carbon fiber.

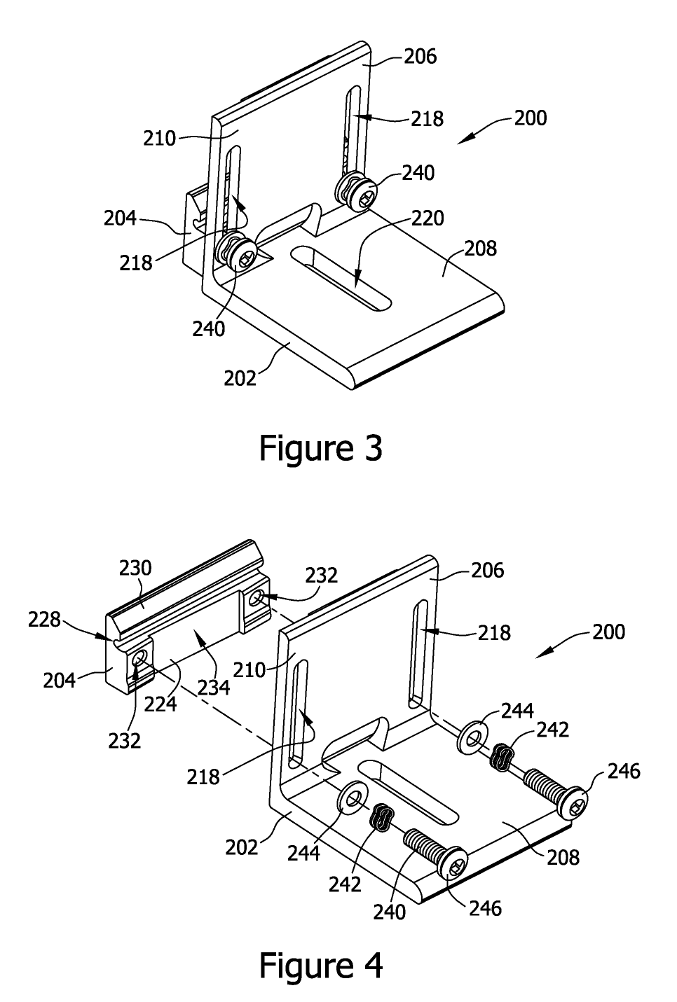

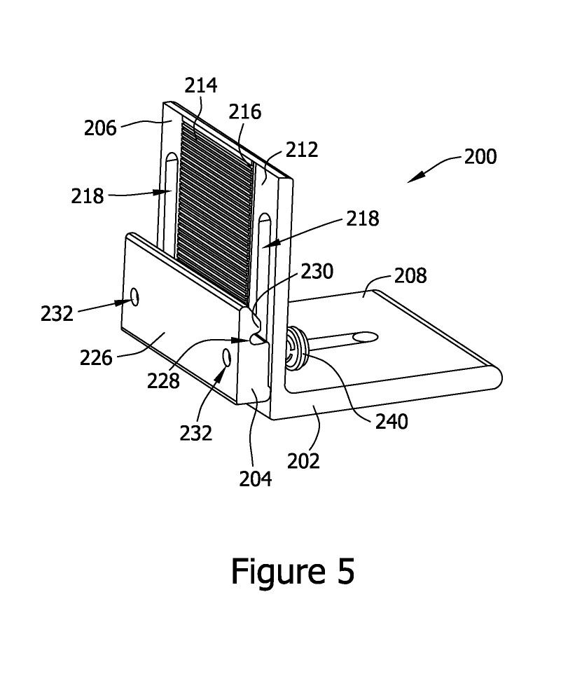

Referring now to FIGS. 3-5, a mounting bracket is indicated generally at 200. FIG. 3 is a front, perspective view of mounting bracket 200, and FIG. 4 is an exploded view of mounting bracket 200. FIG. 5 is a back, perspective view of mounting bracket 200.

Mounting bracket 200 includes a foot 202 and a backing 204. Foot 202 includes a first wall 206 and a second wall 208. In the exemplary embodiment, first wall 206 is substantially orthogonal to second wall 208 such that foot 202 is substantially L-shaped. In other embodiments, first wall 206 and second wall 208 may be oriented in any configuration that enables mounting bracket 200 to function as described herein.

First wall 206 includes a front surface 210 and a back surface 212. Back surface 212 includes a serrated portion 214 having a plurality of serrations 216. Serrated portion 214 and serrations 216 engage a rail (omitted in FIGS. 3-5 but described below). A pair of parallel, elongate slots 218 is defined in first wall 206. In the exemplary embodiment, serrated portion 214 is between slots 218. As described in detail below, serrations 216 and slots 218 facilitate adjusting a height of the rail 302, and accordingly, solar module 100.

An elongate slot 220 is defined in the second wall 208. Slot 220 is sized to receive a bolt or any other suitable fastening mechanism for mounting foot 202 to a mounting surface (not shown). The mounting surface may include, for example, a roof.

Backing 204 includes a front 224 and a back 226. A cutout 228 is defined in front 224 such that backing includes a clip portion 230. Clip portion 230 engages the rail 302, as described in detail below. In the exemplary embodiment, backing 204 includes a pair of threaded apertures 232 defined therethrough. With mounting bracket 200 assembled, threaded apertures 232 align with slots 218 in foot 202, and serrations 216 fit within a recess 234 between threaded apertures 232.

To assemble mounting bracket 200, in the exemplary embodiment, foot 202 is coupled to backing 204 with screws 240. Alternatively, any suitable fastening mechanism may be used to couple foot 202 to backing 204. Each screw 240 is threaded through a spring 242 and a washer 244 such that spring 242 and washer 244 are between a head 246 of screw 240 and front surface 210 of first wall 206. In the exemplary embodiment, spring 242 is a spring washer. In other embodiments, spring 242 may be any other suitable resilient element including, for example, a coil spring. Further, each screw 240 is inserted through one of slots 218 to threadably engage one of threaded apertures 232 in backing 204. Spring 242 provides a preload to bias backing 204 toward foot 202.

Foot 202 and backing 204 may be constructed of any suitable material for the purposes described herein. In the exemplary embodiment, foot 202 and backing 204 are made of aluminum. In other embodiments, foot 202 and/or backing 204 may be made of any suitable material including for example, other metals, plastics, etc.

In the exemplary embodiment, foot 202 and backing 204 are each integrally formed as one piece. More particularly, foot 202 and backing 204 are die cast. In other embodiments, foot 202 and/or backing 204 may be formed by any other suitable process including, for example, stamping or machining. Further, in some embodiments, foot 202 and/or backing 204 may be formed from separate material that are joined together to form foot 202 and/or backing 204, such as by welding.

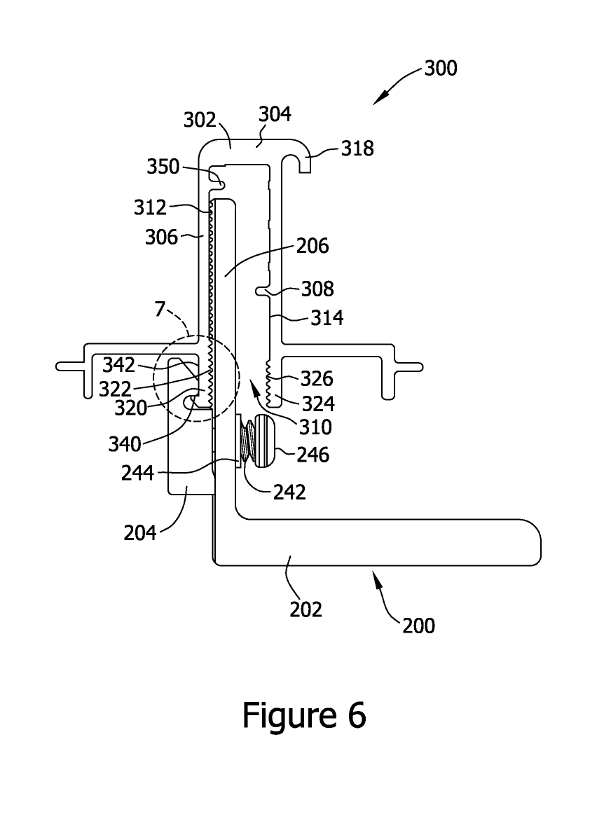

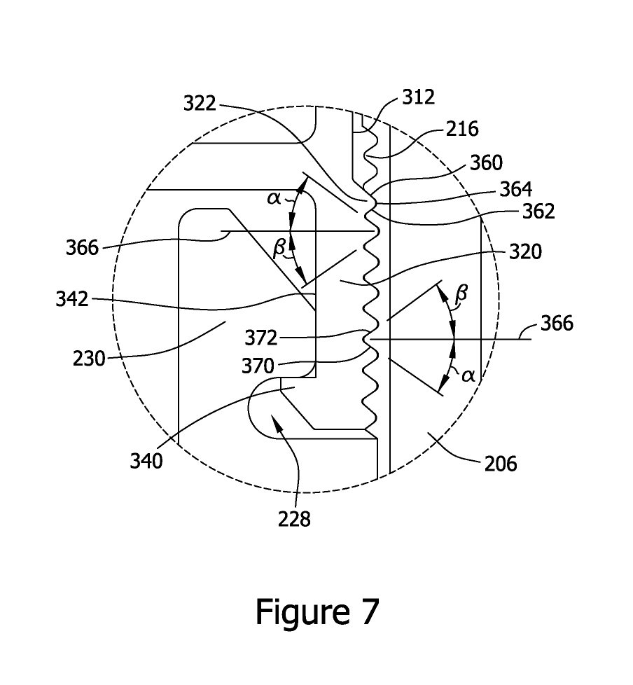

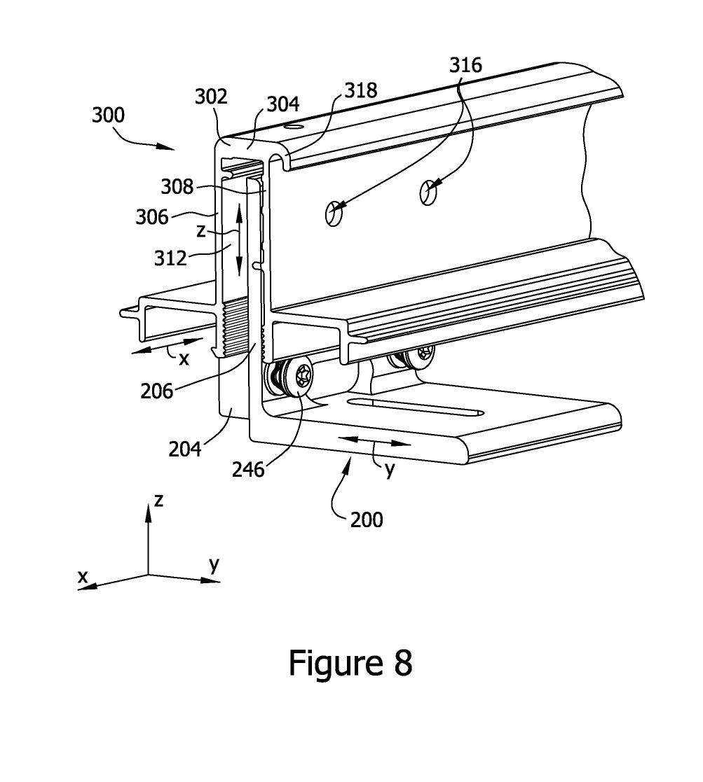

Referring now to FIGS. 6-8, a mounting assembly is indicated generally at 300. FIG. 6 is a side view of mounting assembly 300, FIG. 7 is an enlarged view of a portion of FIG. 6 taken along area 7, and FIG. 8 is a perspective view of mounting assembly 300.

Mounting assembly 300 includes mounting bracket 200 coupled to a rail 302. Rail 302 includes a top 304, a first wall 306, and a second wall 308 that define a substantially U-shaped channel 310. When mounting bracket 200 is coupled to rail 302, first wall 206 of foot 202 nests between an interior surface 312 of first wall 306 and an interior surface 314 of second wall 308.

One or more solar modules 100 (shown in FIG. 1) are coupled to rail 302. In the exemplary embodiment, solar module 100 is coupled to second wall 308 of rail 302 using a plurality of apertures 316 defined in second wall 208 and a hook portion 318 of top 304. Alternatively, solar module 100 is coupled to rail 302 using any methods that enable mounting assembly 300 to function as described herein. For example, in some embodiments, at least one solar module 100 is coupled to first wall 306. With solar module 100 coupled to rail 302, adjusting a position of rail 302 with respect to mounting bracket 200 also adjusts a position of solar module 100.

First wall interior surface 312 of rail 302 includes a first serrated portion 320 having first serrations 322. Similarly, second wall interior surface 314 includes a second serrated portion 324 having second serrations 326. First serrations 322 on rail 302 engage serrations 216 on foot 202 to secure foot 202 with respect to rail 302. A lip 340 extends from an exterior surface 342 of first wall 306. Lip 340 inserts into cutout 228 and clip portion 230 engages lip 340. With screws 240 tightened, springs 242 and washers 244 exert a force on foot 202 to maintain engagement between serrations 216 and first serrations 322.

To adjust the position of rail 302 with respect to mounting bracket 200, screws 240 are loosened. With screws 240 sufficiently loosened, to adjust rail 302 in an x-direction (shown in FIG. 8), lip 340 can be slid along clip portion 230. To adjust rail 302 in a z-direction (shown in FIG. 8), when first serrations 322 are not firmly engaged with serrations 216, rail 302 can be raised and/or lowered with respect to foot 202. When raising and/or lowering rail 302, screws 240 raise and/or lower accordingly in slots 218. When rail 302 is at a desired height, screws 240 are tightened to secure rail 302 with respect to mounting bracket 200.

Rail 302 may be adjusted with respect to mounting bracket 200 either before or after mounting bracket 200 is mounted to the mounting surface. Moreover, while only one mounting bracket 200 is illustrated in the Figures, in some embodiments, a plurality of mounting brackets 200 are used to secure rail 302 to the mounting surface.

In the exemplary embodiment, first wall interior surface 312 includes a projection 350 extending therefrom. Projection 350 limits movement of rail 302 with respect to foot 202 in the z-direction. Specifically, when rail 302 is lowered with respect to foot 202, projection 350 eventually contacts foot 202, inhibiting further lowering of rail 302. Slots 218 also limit movement of rail 302 with respect to foot 202 in the z-direction.

As shown in FIG. 7, first serrations 322 and serrations 216 are asymmetrical in the exemplary embodiment. That is, each of first serrations 322 includes a substantially planar top surface 360 and a substantially planar bottom surface 362 connected by an arcuate portion 364. With respect to a plane 366 in a y-direction (shown in FIG. 8), top surface 360 is oriented at a first angle α, and bottom surface 362 is oriented at a second angle β. First angle α is greater than second angle β. To engage first serrations 322, each of serrations 216 include a substantially planar bottom surface 370 oriented at first angle α and a substantially planar top surface 372 oriented at second angle β with respect to plane 366.

Because of the asymmetrical configuration of first serrations 322 and serrations 216, a different force may be applied by an installer to raise rail 302 with respect to foot 202 than the force applied to lower rail 302. Further, due to the asymmetrical configuration, when screws 240 are partially loosened, first serration bottom surfaces 362 remained seated on serration top surfaces 372, maintaining engagement between first serrations 322 and serrations 216. With screws 240 partially loosened, an operator may adjust rail 302 with respect to foot 202.

Additionally, as explained above, springs 242 apply a force on foot 202 to facilitate maintaining engagement between first serrations 322 and serrations 216. Because of the force applied by springs 242, first serrations 322 and serrations 216 may remain at least partially engaged when screws 240 are loosened. As screws 240 are loosened, first serrations 322 gradually pull away from serrations 216. While first serrations 322 and serrations 216 remain partially engaged, the further first serrations 322 pull away from serrations 216, the less vertical force is required to raise and/or lower rail 302.

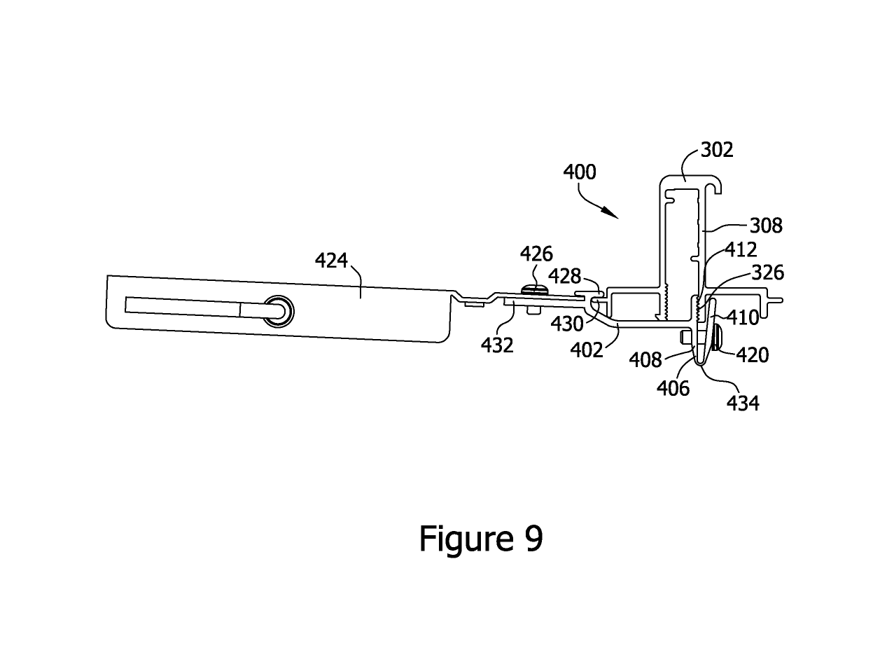

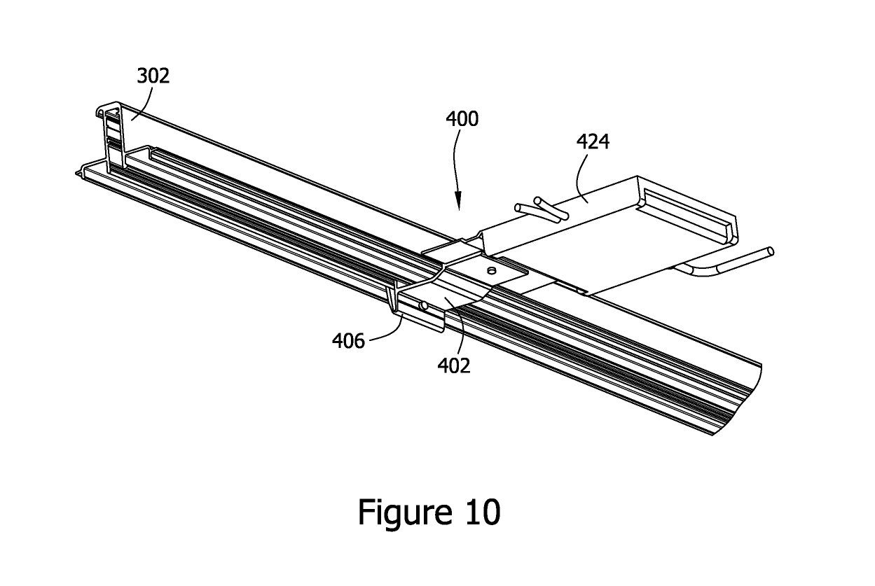

Referring now to FIGS. 9 and 10, an inverter bracket assembly is indicated generally at 400. FIG. 9 is a side view of inverter bracket assembly 400, and FIG. 10 is a bottom perspective view of inverter bracket assembly 400.

Inverter bracket assembly 400 includes an inverter bracket 402 that couples to rail 302. Inverter bracket 402 includes a clip 406 having a first jaw 408 and a second jaw 410 coupled together by a living hinge 434. First jaw 408 includes serrations 412 for engaging second serrations 326 of rail 302. In the exemplary embodiment, serrations 412 and second serrations 326 are asymmetrical, similar to serrations 216 and serrations 322. Alternatively, serrations 412 and/or second serrations 326 may be symmetrical. Serrations 412 engage second serrations 326 when inverter bracket 402 is coupled to rail 302. Clip 406 includes a screw 420 inserted through second jaw 410 and threadably engaged with first jaw 408. By tightening screw 420, first and second jaws 408 and 410 clamp together, securing clip 406 to second wall 308 of rail 302.

In the exemplary embodiment, an inverter 424 is coupled to and supported by inverter bracket 402. Alternatively, any component related to solar module 100 may be coupled to and supported by inverter bracket 402. Inverter bracket 402 includes a support shelf 432 to which inverter 424 is coupled. To couple the two components, a screw 426 is threaded through inverter 424 and support shelf 432. Inverter bracket 402 also includes a shelf 428 that rests on an external ledge 430 of rail 302. Shelf 428 facilitates supporting inverter 424 when inverter is coupled to inverter bracket 400.

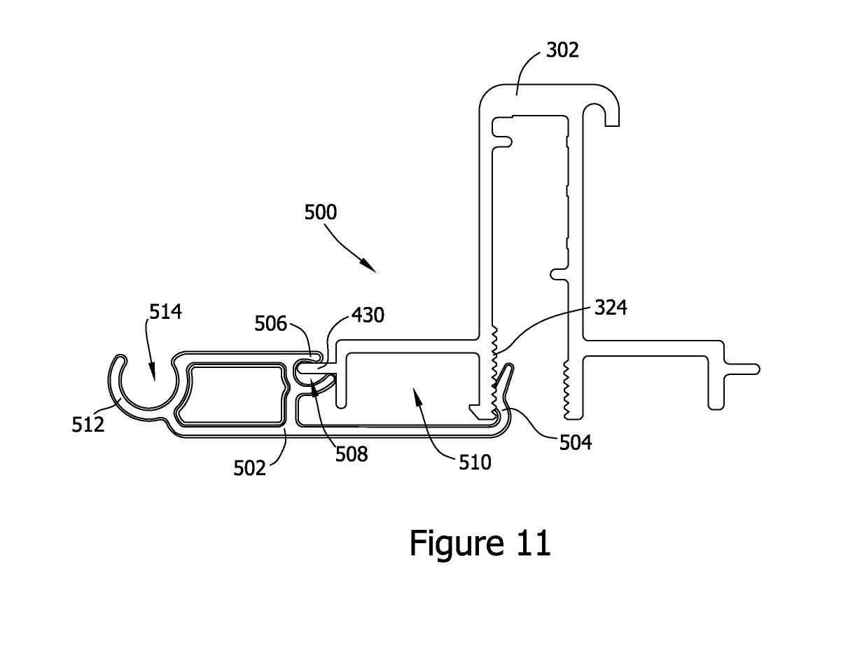

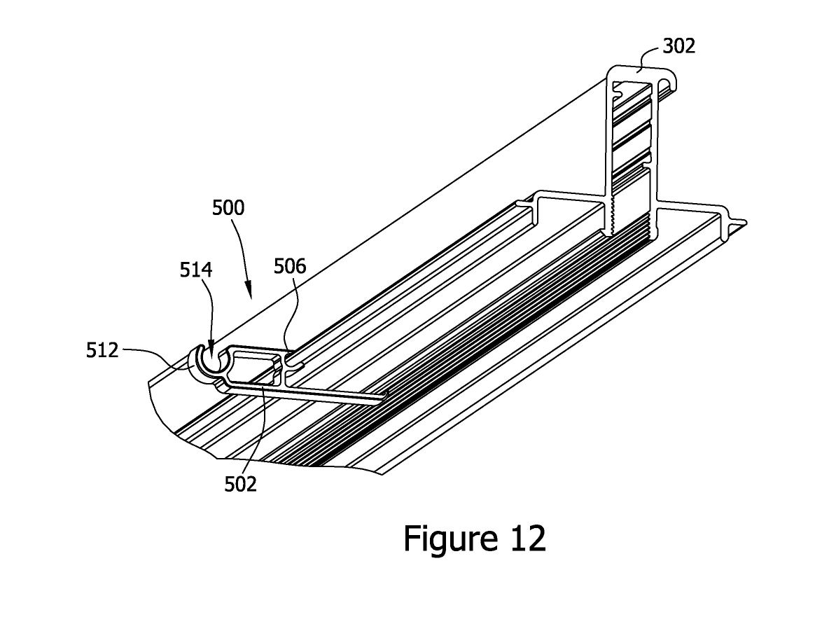

Referring now to FIGS. 11 and 12, a wire clip assembly is indicated generally at 500. FIG. 11 is a side view of wire clip assembly 500, and FIG. 12 is a bottom perspective view of wire clip assembly 500.

Wire clip assembly 500 includes a wire clip 502 that couples to rail 302. Wire clip 502 includes a finger 504 and a clip 506 that defines a receptacle 508. To couple wire clip 502 to rail 302, external ledge 430 of rail 302 fits into receptacle 508, and finger 504 engages first serrations 322. With wire clip 502 coupled to rail 302, a wire channel 510 is defined between wire clip 502 and rail 302. A wire and/or cable (not shown) can be threaded through channel 510 or a similar gap. Wire clip also includes an arcuate portion 512 that defines a pocket 514. Pocket 514 is sized and oriented to hold a portion of a wire and/or cable.

Embodiments of the methods and systems described herein achieve superior results compared to prior methods and systems. For example, the mounting brackets described herein simplify the mounting “foot” so that it is pre-assembled and is adjustable in multiple directions or axes. In this way, the bracket enables the system to adapt to variances in the mounting surface (e.g., a roof), and to allow more room for error by the installer of the system. Embodiments of the system may also reduce assembly labor, time and therefore the cost of installing the system. The system may also be cheaper due to the reduced number of fasteners needed at an installation site. Furthermore, the above-described mounting brackets enable a position of a rail, and accordingly, a solar module, to be adjusted with respect to the mounting brackets. Moreover, as the mounting brackets nest within the rail, the mounting brackets enable a relatively low-profile mounting assembly. Generally, solar modules installed using embodiments of the mounting brackets may be easier, faster, less expensive and/or safer to install than solar modules utilizing prior systems.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A mounting bracket for use with a solar module, the mounting bracket comprising:
a foot including a first wall and a second wall oriented orthogonal to the first wall, the first wall including serrations configured to engage serrations on a rail to adjust a height of the rail with respect to the foot; and
a backing configured to be coupled to the foot and secure the mounting bracket to the rail.

2. A mounting bracket in accordance with claim 1, wherein the first wall serrations are asymmetrical.

3. A mounting bracket in accordance with claim 1, wherein the backing comprises a clip engaging a lip of the rail.

4. A mounting bracket in accordance with claim 1, wherein the first wall of the foot includes at least one elongate slot defined therein and the backing includes at least one threaded aperture, the at least one elongate slot aligned with the at least one threaded aperture to facilitate coupling the foot to the backing with a fastening device.

5. A mounting bracket in accordance with claim 4, further comprising at least one fastening device configured to insert through the at least one elongate slot and engage the at least one threaded aperture to couple the foot to the backing.

6. A mounting bracket in accordance with claim 5, further comprising a spring configured for placement between the at least one fastening device and the first wall to bias the backing toward the foot when the at least one fastening device is inserted through the at least one elongate slot and engaged with the at least one threaded aperture to couple the foot to the backing.

7. A mounting bracket in accordance with claim 1, wherein the backing further includes a recess defined therein to align with the serrations on the first wall when the backing is coupled to the foot.

8. A mounting bracket in accordance with claim 1, wherein the second wall includes an elongate slot defined therein, the second wall elongate slot configured to receive a fastening device to couple the foot to a mounting surface.

9. A mounting assembly for use with a solar module, the mounting assembly comprising:
a rail including a top, a first wall, and a second wall that define a slot, the first wall having an interior surface including serrations along a portion of the interior surface; and
at least one mounting bracket coupled to the rail, the at least one mounting bracket comprising:
a foot positioned in the slot, the foot comprising serrations that engage the rail serrations, wherein the foot serrations and the rail serrations facilitate adjusting a height of the rail with respect to the foot; and
a backing coupled to the foot to secure the mounting bracket to the rail.

10. A mounting assembly in accordance with claim 9, wherein the foot serrations and the rail serrations are asymmetrical.

11. A mounting assembly in accordance with claim 9, wherein the rail further comprises a lip extending from an exterior surface of the rail first wall, and the backing comprises a clip to engage the lip.

12. A mounting assembly in accordance with claim 9, wherein the foot is coupled to the backing using at least one fastening device threaded through a spring and a washer.

13. A mounting assembly as set forth in claim 12, wherein the spring provides a preload to bias the backing toward the foot to facilitate engaging the foot serrations with the rail serrations.

14. A mounting assembly as set forth in claim 9 in combination with the solar module.

15. A mounting assembly as set forth in claim 9 wherein the foot is positioned in the slot and releasably engages the interior surface to facilitate adjusting a height of the rail with respect to the foot.

16. A component mounting bracket for use with a solar module mounting rail, the component mounting bracket comprising:
a clip including a first jaw and a second jaw, the first jaw including serrations configured to engage serrations on a wall of a rail to couple the component mounting bracket to the rail, the second rail configured to contact a surface of the wall of the rail opposite the rail serrations; and
a support shelf configured to support and couple a component to the component mounting bracket.

17. A component mounting bracket in accordance with claim 16, wherein the component is an inverter.

18. A component mounting bracket in accordance with claim 16, further comprising a fastener coupled through the first jaw and the second jaw to facilitate varying a distance between the first jaw and the second jaw to secure the clip to the wall of the rail.

19. A component mounting bracket in accordance with claim 16, further comprising a shelf configured to rest on an external ledge of the rail, and wherein the first jaw is coupled to the second jaw by a living hinge.

20. A wire clip assembly for use with a solar module mounting rail, the component mounting bracket comprising:
a finger including serrations configured to engage serrations on a wall of a rail; and
a clip defining a receptacle configured to engage an external ledge of the rail, the finger and the clip configured to cooperatively couple the wire clip to the rail, the finger and the clip cooperatively defining at least a portion of a wire channel between the wire clip and the rail when the wire clip is coupled to the rail.

21. A wire clip assembly in accordance with claim 20, further comprising an arcuate portion defining a pocket configured to hold a portion of a wire or cable.
